(19) United States
(12) Patent Application Publication
(10) Pub. No.: US 2008/0157232 A1
(43) Pub. Date: Jul. 3, 2008

(54) SEMICONDUCTOR DEVICE AND METHOD OF FABRICATING THE SAME, AND NAND GATE CIRCUIT USING THE SEMICONDUCTOR DEVICE

(76) Inventor: Jung-Ho Ahn, Seoul (KR)

Correspondence Address: SHERR & NOURSE, PLLC, 620 HERNDON PARKWAY, SUITE 200, HERNDON, VA, 20170, US

(21) Appl. No.: 11/954,193

(22) Filed: Dec. 11, 2007

(30) Foreign Application Priority Data
Dec. 27, 2006 (KR) 10-2006-0134834

(51) Int. Cl. H01L 29/78; H01L 21/336

(52) U.S. Cl. 257/412; 438/282; 257/E29.255; 257/E21.409

(57) ABSTRACT

A method of forming a semiconductor device that can include forming a channel region in a semiconductor substrate; forming a first gate electrode and a second gate electrodes over the semiconductor substrate, the first gate electrode and the second gate electrode being spaced apart from each other at a predetermined distance; forming spacers on sidewalls of the first gate electrode and the second gate electrode and over the semiconductor substrate; forming source/drain regions in the semiconductor substrate; forming a first interlayer insulating layer and a second interlayer insulating over the semiconductor substrate; forming a plurality of contact holes in the first interlayer insulating layer and the second interlayer insulating; and then forming a contact plug in the plurality of contact holes.

The present application claims priority under 35 U.S.C. 119 to Korean Patent Application No. 10-2006-0134834 (filed on Dec. 27, 2006), which is hereby incorporated by reference in its entirety.

### BACKGROUND

An integrated circuit may employ a plurality of transistors of various types. The size of the integrated circuit have become smaller over time, and thus, there is may be a need to gradually reduce the size of the transistors.

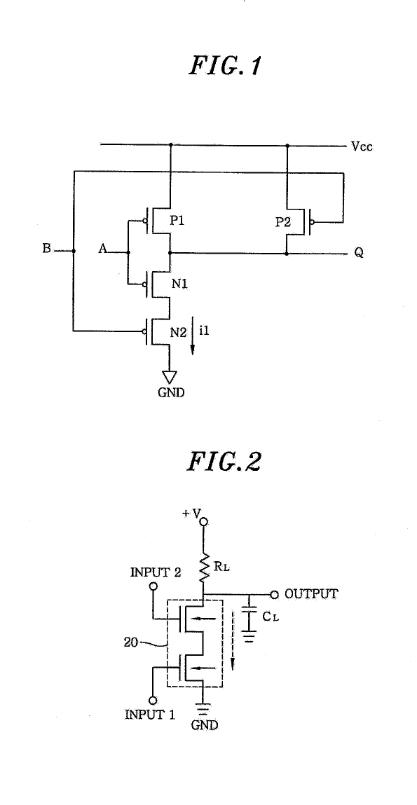

As illustrated in example FIG. 1, a NAND gate circuit may be configured to output a signal on which a NAND operation may be performed by using two input signals A and B as inputs.

The NAND gate circuit may include PMOS transistor P1, NMOS transistors N1 and N2 and PMOS transistor P2. PMOS transistor P1 may transfer a logic high value to output terminal Q when input signal A has a logic low value. NMOS transistors N1 and N2 may use input signals A and B, respectively, as inputs, and may be turned on when both input signals A and B have a high logic value and low transfer logic values to output terminal Q. PMOS transistor P2 may transfer a high logic value to output terminal Q when input signal B has a low logic value.

In the operation of such a NAND gate structure, when both input signals A and B have a high logic value, PMOS transistors P1 and P2 may be turned off and one of NMOS transistors N1 and N2 may be turned off, so that a high logic value is output to output terminal Q. Moreover, when both input signals A and B have a low logic value, PMOS transistors P1 and P2 may be turned on and NMOS transistors N1 and N2 are turned off, so that a high logic value is output to output terminal Q.

Because the NAND gate circuit may typically include two PMOS transistors and two NMOS transistors, it is difficult to achieve a highly integrated circuit.

### SUMMARY

Embodiments relate to a semiconductor device such as a NAND gate and a method of fabricating the same in which an overall chip area can be decreased significantly by reducing the number of structural elements necessary for a NAND gate.

Embodiments relate to a semiconductor device such as a NAND gate and a method of fabricating the same in which either a PMOSFET or a NMOSFET can be selectively used as a transistor constituting a switching element.

Embodiments relate to a semiconductor device that can include: a semiconductor substrate having source/drain regions and a channel region; a first gate electrode and a second gate electrodes formed over the semiconductor substrate spaced apart from each other at a predetermined distance; spacers formed on sidewalls of the first gate electrode and the second gate electrode and over the source/drain regions and the channel region; at least one interlayer insulating layer having a plurality of contact holes formed over the semiconductor substrate including the first gate electrode and the second gate electrode; and a plurality of contact plugs formed within a respective contact hole.

Embodiments relate to a method of fabricating a semiconductor device that can include at least one of the following steps: forming a channel region in a semiconductor substrate; forming a first gate electrode and a second gate electrodes over the semiconductor substrate, the first gate electrode and the second gate electrode being spaced apart from each other at a predetermined distance; forming spacers on sidewalls of the first gate electrode and the second gate electrode and over the semiconductor substrate; forming source/drain regions in the semiconductor substrate; forming a first interlayer insulating layer and a second interlayer insulating over the semiconductor substrate; forming a plurality of contact holes in the first interlayer insulating layer and the second interlayer insulating; and then forming a contact plug in the plurality of contact holes.

Embodiments relate to a method of fabricating a semiconductor device that can include at least one of the following steps: providing a switching element including a transistor having a plurality of gates; applying a first input signal to a first gate of the transistor; applying a second input signal to a second gate of the transistor; grounding a drain of the transistor; connecting a source of the transistor to an output terminal; and controlling the channel according to the first input signal and the second input signal by forming the channel between the drain and the source.

### DRAWINGS

Example FIG. 1 illustrates a circuit diagram of a NAND gate.

Example FIG. 2 illustrates a circuit diagram of a NAND gate, in accordance with embodiments.

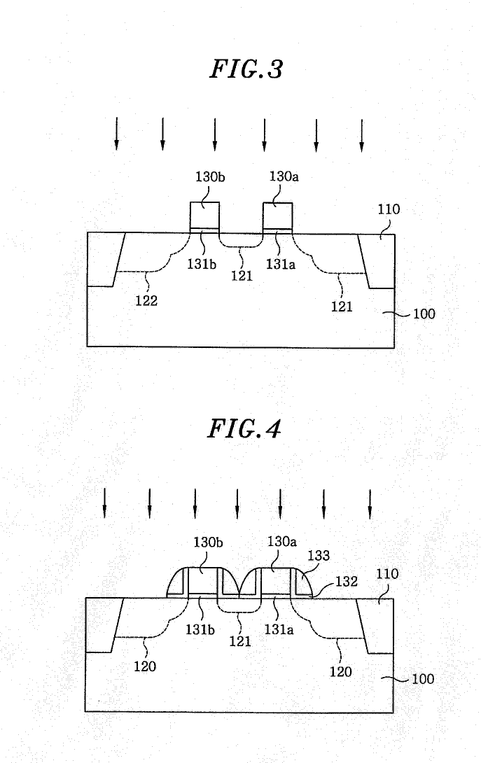

Example FIGS. 3 to 8 illustrate a method of fabricating a semiconductor device, in accordance with embodiments.

### DESCRIPTION

As illustrated in example FIG. 2, a NAND gate circuit in accordance with embodiments can include switching element 20 having a pair of gate electrodes adjacent to each other on and/or over a semiconductor substrate. Switching element 20 can be selectively constructed as at least one of a NMOSFET and a PMOSFET. In order for the circuit to operate as a NAND gate circuit, only when a high signal is input to both first input Input 1 and second input Input 2, a low signal can be output to output terminal Output.

However, when a low signal is input to both first input Input 1 and second input Input 2, or any one of first input Input 1 and second input Input 2, a high signal can be output to output terminal Output.

Particularly, in a circuit including load resistor R_{L} and internal capacitor C_{L}, if an input is applied to any one of input terminal Input 1 and input terminal Input 2, a channel can be formed below the terminal within the substrate to which the input is applied. Thus, a path through which current will pass does not exist.

However, if a high signal is input to both input terminal Input 1 and input terminal Input 2, a channel can be formed below both the first gate electrode and the second gate electrode. Thus, output terminal Output can be connected to ground GND and the current exits.

If input terminal Input 1 and input terminal Input 2 are formed in the gate, they can be considered independent terminals. If the input is applied to one of input terminal Input 1 and input terminal Input 2, a partial channel can be formed. However, in order for current to flow through output terminal Output, the channel has to be formed both in both gates electrodes and thus, a low signal can be output through output terminal Output.

In essence, when a high signal is input to only one of the gate electrodes, a high signal can be monitored at output terminal Output. Only when a high signal is input to both gate electrodes, a low signal can be monitored at output terminal Output.

As illustrated in example FIG. 3, a semiconductor device in accordance with embodiments can be manufactured by forming isolation layers 110 for defining active regions in semiconductor substrate 100. A channel may then be formed in semiconductor substrate 100 by performing an impurity implantation process.

First gate oxide layer 131a and second gate oxide layer 131b can then be formed on and/or over semiconductor substrate 100 spaced apart spatially from each other at a predetermined distance. First gate electrode 130a and second gate electrode 130b can be are formed on and/or over first gate oxide layer 131a and second gate oxide layer 131b, respectively spaced apart spatially from each other at a predetermined distance.

After first gate electrode 130a and second gate electrode 130b are formed, an impurity implantation process can be performed on and/or over semiconductor substrate 100. Particularly, a process of implanting impurity ions into semiconductor substrate 100 can be performed using first gate electrode 130a and second gate electrode 130b as masks. In the event an n-type channel (e.g., a first conductive type) element is to be fabricated, arsenic (As) or phosphorus (P) (e.g., a second conductive type impurity) can be implanted into a P-type substrate. On the other hand, in the event a p-type channel (e.g., a second conductive type) element is to be fabricated, BF₂ or B (e.g., a first conductive type impurity) can be implanted into an n-type substrate.

Through such an ion implantation process, second impurity region 122 can be formed in semiconductor substrate 100. Second impurity region 122 can serve as a region where source/drain regions of a lightly doped drain (LDD) structure can be formed. First impurity region 121 can be formed in semiconductor substrate 100 in a region between first gate electrode 130a and second gate electrode 130b. As mentioned above, formation of the channel can also be performed on semiconductor substrate 100 below first gate oxide layer 131a and second gate oxide layer 131b by implanting impurity ions into semiconductor substrate 100.

As illustrated in example FIG. 4, first spacer 132 and second spacer 133 can then be formed on both sides of first gate electrode 130a and second gate electrode 130b, respectively. Particularly, first spacer 132 for both first gate electrode 130a and second gate electrode 130b can be formed on and/or over first impurity region 121 and second spacer 133 can be formed on and/or over first spacer 132. First spacer 132 can be formed on one side of first gate electrode 130a and second gate electrode 130b and consecutively on and/or over semiconductor substrate 100. Accordingly, the region between first gate electrode 130a and second gate electrode 130b can be filled with first spacer 132 and second spacer 133.

An impurity ion implantation process for forming source/drain regions 120 having a LDD structure in semiconductor substrate 100 can then be performed using first gate electrode 130a, second gate electrode 130b, first spacer 132 and second spacer 133 as masks. The implanted impurity ions may vary depending on the type of a device to be fabricated.

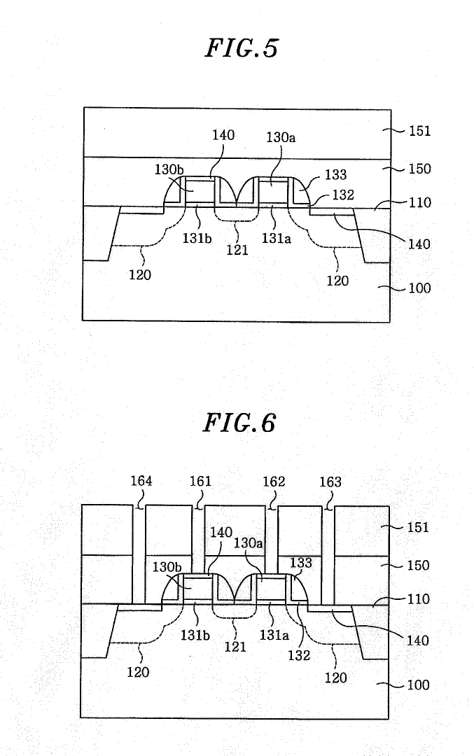

As illustrated in example FIG. 5, a silicide process for ohmic contact can be performed to form silicide layer 140 on and/or first gate electrode 130a, second gate electrode 130b and source/drain regions 120.

First interlayer insulating layer 150 can then be formed having a predetermined thickness on and/or over semiconductor substrate 100 including silicide layer 140. Second interlayer insulating layer 151 can then be formed on and/or over first interlayer insulating layer 150.

As illustrated in example FIG. 6, a photoresist can then be coated on and/or over second interlayer insulating layer 151 and then patterned in order to prepare a process of etching second interlayer insulating layer 151 and first interlayer insulating layer 150. The photoresist can then be patterned and second interlayer insulating layer 151 and first interlayer insulating layer 150 can then be etched using the patterned photoresist as an etch mask to form first contact hole 161 to expose the uppermost surface of silicide layer 140 provided on and/or over first gate electrode 130a, second contact hole 162 to expose the uppermost surface of silicide layer 140 provided on and/or over second gate electrode 130b, third contact hole 163 to expose the uppermost surface of silicide layer 140 provided on and/or over source/drain region 120 and fourth contact hole 164 to expose the uppermost surface of silicide layer 140 provided on and/or over the other source/drain region 120.

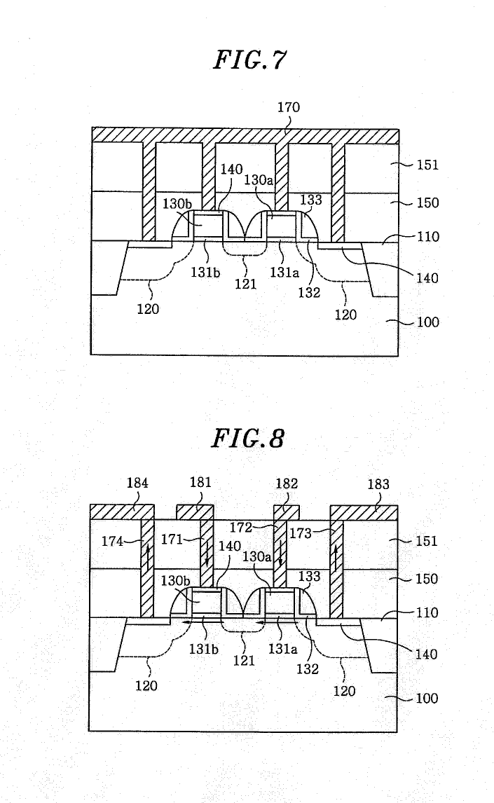

As illustrated in example FIG. 7, metal layer 170 such as tungsten (W) or copper (Cu) for forming an interlayer connection, can then be deposited in contact holes 161,162,163, and 164 and then polished. Particularly, a barrier metal can be deposited in contact holes 161,162,163, and 164, and a metal layer 170 such as tungsten (W) or copper (Cu) for interlayer connection, can then be deposited on and/or over the barrier metal. The metal layer 170 can then be polished.

As illustrated in example FIG. 8, polished metal layer 170 can then be patterned to form first contact plug 171 (serving as a first input terminal) in first contact hole 161, second contact plug 172 (serving as a second input terminal) in second contact hole 162, third contact plug 173 (serving as an output terminal) in third contact hole 163, fourth contact plug 174 (serving as a ground surface) in fourth contact hole 164, first metal wire 181 on and/or over first contact plug 171, second metal wire 182 on and/or over second contact plug 172, third metal wire 183 on and/or over third contact plug 173 and fourth metal wire 184 on and/or over fourth contact plug 174.

Arrows designate the flows of current when a high signal, that is, an input signal is input through first contact plug 171 and second contact plug 172. In other words, in the event that a high signal is input through first contact plug 171 and second contact plug 172, third contact plug 173 becomes conductive to fourth contact plug 174, i.e., the ground surface through a channel and first impurity region 121 formed within semiconductor substrate 100 under first gate electrode 130a and second gate electrode 130b. Thus, a low signal can be monitored at third contact plug 173, i.e., the output terminal.

As illustrated in example FIG. 8, first input Input 1 can be supplied through first contact plug 171 connected to first gate electrode 130a. Second input Input 1 can be supplied through second contact plug 172 connected to second gate electrode 130b. Third contact plug 173 can serve as the output terminal Output, and fourth contact plug 174 can be grounded. The drain of semiconductor substrate 100 can be electrically connected to third contact plug 173 and the source of semiconductor substrate 100 can serve as ground GRD.

It can be assumed that signals input through first contact plug 171 and second contact plug 172 are the first and second inputs, a signal monitored through third contact plug 173 is the output signal, and fourth contact plug 174 is the ground surface.

Table 1 is a true table of the NAND gate, in accordance with embodiments.

TABLE 1

| Input 1 | Input 2 | Output |
|---|---|---|
| 0 | 0 | 1 |
| 0 | 1 | 1 |
| 1 | 0 | 1 |
| 1 | 1 | 0 |

As illustrated in example FIG. 8 and Table 1, when both the first and second inputs have a low signal, a channel is not formed under first gate electrode 130a and second gate electrode 130b. The output terminal is therefore not conductive to the ground surface and thus, the output signal can be maintained at a high state. The output terminal can be maintained at a high state because it is connected to parasitic capacitor C_{L} as described above.

Moreover, when the first input has a low signal and the second input has a high signal, a channel can be formed in semiconductor substrate 100 under second gate electrode 130b. Thus, the output terminal is not actually connected to the ground surface. In other words, since only second gate electrode 130b is turned on and first gate electrode 130a is in a turn-off state, the NAND circuit can be entirely in a turn-off state, and therefore, the output terminal is in a high state.

Even when the first input has a high signal and the second input has a low signal, only first gate electrode 130a can be turned on and second gate electrode 130b can be in a turn-off state. Thus, the output terminal is not actually connected to the ground surface. Accordingly, the NAND circuit can be entirely in a turn-off state and, therefore, the output terminal can be in a high state.

However, when both the first and second inputs have a high signal, both first gate electrode 130a and second gate electrode 130b are turned on. Thus, the channel connecting the drain connected to third contact plug 173 and the source connected to fourth contact plug 174 is consecutive. Consequently, as the capacitor is discharged by the formed channel, the output signal is in a low state.

In accordance with embodiments, the overall number of elements constituting a NAND gate can be minimized and the degree of integration of devices can be increased accordingly.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate having source/drain regions and a channel region;
a first gate electrode and a second gate electrode formed over the semiconductor substrate spaced apart from each other at a predetermined distance;
spacers formed on sidewalls of the first gate electrode and the second gate electrode and over the source/drain regions and the channel region;
at least one interlayer insulating layer having a plurality of contact holes formed over the semiconductor substrate including the first gate electrode and the second gate electrode; and
a plurality of contact plugs formed within a respective contact hole.

2. The apparatus of claim 1, wherein the plurality of contact plugs comprises a first contact plug electrically connected to the first gate electrode, a second contact plug electrically connected to the second gate electrode, and a third contact plug and a fourth contact plug electrically connected to a respective source/drain region.

3. The apparatus of claim 2, further comprising:
a first metal wire formed over the at least one interlayer insulating layer and connected to the first contact plug;
a second metal wire formed over the at least one interlayer insulating layer and connected to the second contact plug;
a third metal wire formed over the at least one interlayer insulating layer and connected to the third contact plug; and
a fourth metal wire formed over the at least one interlayer insulating layer and connected to the fourth contact plug.

4. The apparatus of claim 3, wherein the contact plugs and the metal wires are composed of at least one of tungsten and copper.

5. The apparatus of claim 1, further comprising a channel having an impurity region formed in the semiconductor substrate between the first gate electrode and the second gate electrode.

6. The apparatus of claim 1, wherein the spacers are formed in a region between the first gate electrode and the second gate electrode.

7. The apparatus of claim 1, wherein the spacers include a first spacer formed on the sidewalls of the first gate electrode and the second gate electrode and over the sourced/drain regions and the channel region, and a second spacer formed over the first spacer.

8. The apparatus of claim 1, further comprising a silicide layer formed the first gate electrode, the second gate electrode and the source/drain regions.

9. A method comprising:
forming a channel region in a semiconductor substrate;
forming a first gate electrode and a second gate electrodes over the semiconductor substrate, the first gate electrode and the second gate electrode being spaced apart from each other at a predetermined distance;
forming spacers on sidewalls of the first gate electrode and the second gate electrode and over the semiconductor substrate;
forming source/drain regions in the semiconductor substrate;
forming a first interlayer insulating layer and a second interlayer insulating over the semiconductor substrate;
forming a plurality of contact holes in the first interlayer insulating layer and the second interlayer insulating; and then
forming a contact plug in the plurality of contact holes.

10. The method of claim 9, wherein forming the contact holes comprises:
forming a first contact hole to expose a portion of the uppermost surface of the first gate electrode;
forming a second contact hole to expose a portion of the uppermost surface of the second gate electrode;
forming a third contact hole to expose a portion of one of the source/drain regions; and then
forming a fourth contact hole to expose a portion of the other one of the source/drain regions.

11. The method of claim 9, wherein forming the contact holes comprises:
coating a photoresist over the second interlayer insulating layer;
patterning the photoresist; and then
etching the second interlayer insulating layer and the first interlayer insulating using the patterned photoresist as an etch mask.

12. The method of claim 9, further comprising forming a silicide layer over the first gate electrode, the second gate electrode and the source/drain regions after forming the spacers.

13. The method of claim 12, wherein forming the contact holes comprises:
forming a first contact hole to expose a portion of the uppermost surface of the silicide layer provided over the first gate electrode;
forming a second contact hole to expose a portion of the uppermost surface of the silicide layer provided over the second gate electrode;
forming a third contact hole to expose a portion of the uppermost surface of the silicide layer provided over one of the source/drain regions; and then
forming a fourth contact hole to expose a portion of the uppermost surface of the silicide layer provided over the other one of the source/drain regions.

14. The method of claim 12, wherein forming the contact holes comprises:
coating a photoresist over the second interlayer insulating layer;
patterning the photoresist; and then
etching the second interlayer insulating layer and the first interlayer insulating using the patterned photoresist as an etch mask to expose a portion of the uppermost surface of the silicide layers.

15. The method of claim 9, wherein forming the source/drain regions comprises:
performing a first ion implantation process on the semiconductor substrate to form a pair of impurity regions in the semiconductor substrate after forming the first gate electrode and the second gate electrode; and then
performing a second ion implantation process on the semiconductor substrate by using the first gate electrode, the second gate electrode and the spacers as ion implantation masks after forming spacers.

16. The method of claim 9, wherein the spacers include a first spacer formed on the sidewalls of the first gate electrode and the second gate electrode and over the source/drain regions and the channel region, and a second spacer formed over the first spacer.

17. A method comprising:
providing a switching element including a transistor having a plurality of gates;
applying a first input signal to a first gate of the transistor;
applying a second input signal to a second gate of the transistor;
grounding a drain of the transistor;
connecting a source of the transistor to an output terminal; and then
controlling the channel according to the first input signal and the second input signal by forming the channel between the drain and the source.

18. The method of claim 17, wherein the transistor comprises at least one of a NMOSFET and a PMOSFET.

19. The method of claim 17, further comprising providing a resistor connected to the output terminal.
